(19) United States
(12) Patent Application Publication
(10) Pub. No.: US 2012/0270142 A1
(43) Pub. Date: Oct. 25, 2012

(54) PHOTOSENSITIVE COMPOSITION AND METHOD OF MANUFACTURING A SUBSTRATE FOR A DISPLAY DEVICE USING THE SAME

(75) Inventors: Hi-Kuk LEE, Yongin-si (KR); Su-Yeon SIM, Changwon-si (KR); Sang-Hyun YUN, Suwon-si (KR); Cha-Dong KIM, Hwaseong-si (KR); Jung-In PARK, Seoul (KR); Byung-Uk KIM, Hwaseong-si (KR); Jin-Sun KIM, Hwaseong-si (KR); Tae-Hoon YEO, Hwaseong-si (KR); Hyoc-Min YOUN, Hwaseong-si (KR); Sang-Hoon LEE, Hwaseong-si (KR)

(73) Assignee: SAMSUNG ELECTRONICS CO., LTD., Suwon-si (KR)

(21) Appl. No.: 13/358,385

(22) Filed: Jan. 25, 2012

(30) Foreign Application Priority Data
Apr. 19, 2011 (KR) 10-2011-0036065

(51) Int. Cl. G03F 7/20; G03F 7/031

(52) U.S. Cl. 430/7; 430/281.1; 430/325; 430/319

(57) ABSTRACT

A photosensitive composition and a method of manufacturing a substrate used for a display device are disclosed. The photosensitive composition includes an acrylic based copolymer, a photo-initiator, a photo-sensitizer and a solvent. Thus, a photosensitivity of the photosensitive composition for ultra violet light of a long wavelength may be improved.

### CROSS REFERENCE TO RELATED APPLICATION

This application claims priority from and the benefit of Korean Patent Application No. 2011-0036065, filed on Apr. 19, 2011, which is hereby incorporated by reference for all purposes as if fully set forth herein.

### BACKGROUND OF THE INVENTION

1. Field of the Invention

Exemplary embodiments of the present invention relate to a photosensitive composition and a method of manufacturing a substrate for a display device using the photosensitive composition. More particularly, exemplary embodiments of the present invention relate to a photosensitive composition used for manufacturing a substrate for a display device and a method of manufacturing a substrate for a display device using the photosensitive composition.

2. Discussion of the Background

Generally, a display substrate including a thin-film transistor (“TFT”) further includes an organic layer, a spacer, a planarized layer, a color filter, etc. The organic layer insulates metal patterns formed from metal layers different from each other or planarizes the display substrate. The organic layer, the spacer and the planarized layer may be formed from a photosensitive composition including organic compounds.

The types of photosensitive compositions may be divided into a positive type and a negative type. A 1,2-quinone diazide compound used for a photo-sensitizer of a photosensitive composition of the positive type is easily denaturalized by heat provided in manufacturing the display substrate, so that a light-transmittance of a thin layer formed from the photosensitive composition may be decreased. The organic layer, the spacer or the color filter is not a thin layer removed in a forming process but remains on the display substrate as a final product, which is different from a photo pattern used for forming the TFT as an etch stopping layer. Thus, such an organic layer, spacer or color filter formed from the positive type photosensitive composition may decrease a display quality.

In contrast, the photosensitive composition of the negative type has higher photosensitivity than that of the positive type and hardly decreases the light-transmittance. However, a resolution of the photosensitive composition of the negative type may be decreased by a developing solution used for developing a photoresist layer or an adhesive strength between the photoresist layer and a lower layer may be low. In addition, a photo-initiator as an essential element of the photosensitive composition of the negative type is generally designed to respond to a wavelength of about 365 nm to be mostly removed in a developing process performed after an exposing process. Therefore, an exposure device using a light source providing light of a short wavelength range is used in order to expose the photosensitive composition of the negative type.

The above information disclosed in this Background section is only for enhancement of understanding of the background of the invention and therefore it may contain information that does not form any part of the prior art nor what the prior art may suggest to a person of ordinary skill in the art.

### SUMMARY OF THE INVENTION

Exemplary embodiments of the present invention provide a photosensitive composition capable of improving a light-transmittance, a resolution, an adhesive strength, and a heat discoloration resistance, etc. and having a high photosensitivity to light excluding the short wavelength range.

Exemplary embodiments of the present invention also provide a method of manufacturing a substrate for a display device using the photosensitive composition.

Additional features of the invention will be set forth in the description which follows, and in part will be apparent from the description, or may be learned by practice of the invention.

An exemplary embodiments of the present invention discloses a photosensitive composition including an acrylic based copolymer, a photo-initiator, a photo-sensitizer represented by Chemical Formula 1, and a solvent.

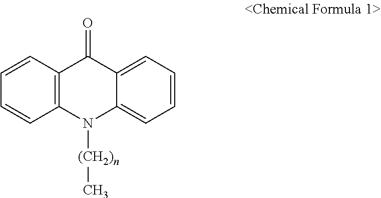

In Chemical Formula 1, “n” represents an integer in a range of 1 to 10.

An exemplary embodiment of the present invention also discloses a method of manufacturing a substrate for a display device using the photosensitive composition. In the method, a photoresist layer is formed on a substrate from a photosensitive composition including an acrylic based copolymer, a photo-initiator, a photo-sensitizer represented by Chemical Formula 1 and a solvent. An electrode layer is formed on the photoresist layer.

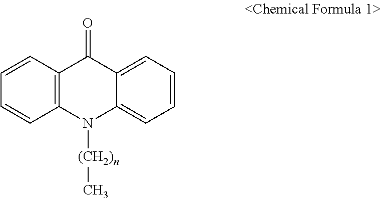

In Chemical Formula 1, “n” represents an integer in a range of 1 to 10.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1, FIG. 2 and FIG. 3 are cross-sectional views illustrating a method of manufacturing a display substrate according to an exemplary embodiment of the present invention.

FIG. 4 is a conceptual view illustrating a digital exposure device used for manufacturing a display substrate according to another exemplary embodiment of the present invention.

FIG. 5 is a plan view illustrating an exemplary embodiment of an exposing process using the digital exposure device in FIG. 4.

FIG. 6 is a cross-sectional view illustrating a method of manufacturing a display substrate according to still another exemplary embodiment of the present invention.

FIG. 7 is a cross-sectional view illustrating a method of manufacturing a color filter substrate according to further still another exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element or layer is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

A photosensitive composition according to exemplary embodiments of the present invention, and an exemplary embodiment of a method of manufacturing a display substrate using the exemplary embodiments of the photosensitive composition will be explained in detail with reference to the accompanying drawings.

Photosensitive Composition

A photosensitive composition according to exemplary embodiments of the present invention includes an acrylic based copolymer, a photo-initiator, a photo-sensitizer, and a solvent. The photosensitive composition may further include a multifunctional monomer, a silicon based compound, and a surfactant, etc. In addition, the photosensitive composition may further include additives. Hereinafter, each constituent will be illustrated in detail.

Acrylic Based Copolymer

The acrylic based copolymer may be prepared from radical-polymerizing an initiator including an azo based compound and an acrylic monomer. For example, the acrylic based copolymer may be prepared by adding 2,2′-azo bis(2,4-dimethylvaleronitrile) into propylene glycol monoethyl acetate, methacrylic acid, styrene and aryl methacrylate.

When a weight-average molecular weight of the acrylic based copolymer is greater than about 3,000, the photosensitive composition may form a layer having a predetermined thickness as a coating layer including the photosensitive composition. The weight-average molecular weight is based on a polystyrene-reduced weight-average molecular weight being measured by a gel permeation chromatography (GPC). In addition, when the weight-average molecular weight of the acrylic based copolymer is less than about 50,000, the acrylic based copolymer may have a state capable of easily dissolving in the solvent. Therefore, the weight-average molecular weight of the acrylic based copolymer may be between about 3,000 and about 50,000. In more detail, the weight-average molecular weight of the acrylic based copolymer may be between about 8,000 and about 12,000.

Photo-Initiator

The photo-initiator is activated by light to cure the photosensitive composition. The photo-initiator absorbs ultra violet (UV) light having a wavelength of about 365 nm and a photosensitivity of the photo-initiator in a wavelength excluding about 365 nm is less than that of the photo-initiator in the wavelength of about 365 nm. Thus, when UV light having a wavelength greater than about 365 nm is irradiated to the photosensitive composition, the photo-initiator is not directly reacted by the UV light but receives energy from the photo-sensitizer activated by the UV light so that the photo-initiator may initiate a photo-reaction of the photosensitive composition.

Examples of a material that can be used for the photo-initiator include a triazine-based compound, a benzoic based compound, an acetophenone-based compound, an imidazole-based compound, an oxime-based compound or a xanthone-based compounds, etc. Detailed examples of the photo-initiator may include 2,4-bistrichloromethyl-6-p-methoxystyryl-s-triazine, 2-p-methoxystyryl-4,6-bistrichloromethyl-s-triazine, 2,4-trichloromethyl-6-triazine, 2,4-trichloromethyl-4-methylnaphthyl-6-triazine, 2-(o-chlorophenyl)-4,5-diphenyl imidazole dimer, 2-(o-chlorophenyl)-4,5-di(m-methoxyphenyl)imidazole dimer, 2-(o-fluorophenyl)-4,5-diphenyl imidazole dimer, 2-(o-methoxyphenyl)-4,5-diphenyl imidazole dimer, 2,4-di(p-methoxyphenyl)-5-phenyl imidazole dimer, 2-(2,4-dimethoxyphenyl)-4,5-diphenyl imidazole dimer, 2-(p-methylmercaptophenyl)-4,5-diphenyl imidazole dimer, [1-[9-ethyl-6-(2-methylbenzoyl)-9H-carbazolyl-3-yl]-1-(o-acetyloxime), benzophenone, p-(diethylamino)benzophenone, 2,2-dichloro-4-phenoxyacetophenone, 2,2-diethoxyacetophenone, 2-dodecylthioxanthone, 2,4-dimethylthioxanthone, 2,4-diethylthioxanthone, 2,2-bis-2-chlorophenyl-4,5,4,5-tetraphenyl-2-1,2-biimidazole, Irgacure® 369 (product name, Ciba® specialty chemicals corporation, Swiss) having a chemical structure of 2-benzyl-2-dimethylamino-1-(4-morpholinophenyl)-butanone-1, Irgacure® 651 (product name, Ciba® specialty chemicals corporation, Swiss) having a chemical structure of 2,2-dimethoxy-1,2-diphenylethan-1-one, Irgacure® 907 (product name, Ciba® specialty chemicals corporation, Swiss), having a chemical structure of 2-methyl-1[4-(methylthio)phenyl]-2-morpholinopropan-1-one, Darocur® TPO (product name, Ciba® specialty chemicals corporation, Swiss) having a chemical structure of 2,4,6-trimethylbenzoyl-diphenyl-phosphineoxide, Irgacure® 819 (product name, Ciba® specialty chemicals corporation, Swiss) having a chemical structure of bis(2,4,6-trimethylbenzoyl)-phenylphosphineoxide, etc. These may be used alone or as a mixture thereof.

When an amount of the photo-initiator is greater than about 0.1 parts by weight with respect to the acrylic based copolymer of about 100 parts by weight, the photosensitivity of the photosensitive composition is increased to improve the ratio of residues. In addition, when the amount of the photo-initiator is less than about 30 parts by weight with respect to the acrylic based copolymer of about 100 parts by weight, the photosensitivity may be easily adjusted to prevent a preservation stability of the photosensitive composition from being decreased, and the photo-initiator may be controlled from excessively promoting a curing reaction, so that an adhesive strength between a residual pattern in a developing process and a lower layer may be prevented from being decreased. Therefore, the amount of the photo-initiator may be between about 0.1 parts by weight and about 30 parts by weight with respect to the acrylic based copolymer of about 100 parts by weight. For example, the photosensitive composition may include the photo-initiator between about 0.1 parts by weight and about 20 parts by weight with respect to the acrylic based copolymer of about 100 parts by weight.

### Photo-Sensitizer

The photo-sensitizer includes an acridine-based compound represented by Chemical Formula 1.

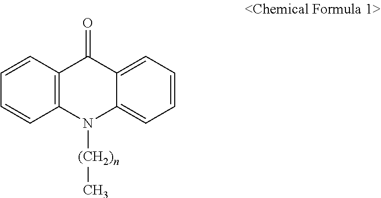

In Chemical Formula 1, “n” represents an integer in a range of 1 to 10.

The acridine-based compound represented by Chemical Formula 1 has high photosensitivity for UV light having a wavelength greater than about 405 nm (long wavelength).

The acridine-based compound represented by Chemical Formula 1 is more quickly reacted than the photo-initiator when exposed to UV light having a wavelength greater than about 405 nm (long wavelength). The acridine-based compound represented by Chemical Formula 1, which absorbs UV light having the long wavelength, transfers energy to the photo-initiator so that a rate of a photo-initiation reaction of the photo-initiator may be promoted (increased). The photo-sensitizer may include a single acridine-based compound alone, which depends on “n”, or a mixture including at least two compounds of the acridine-based compounds, which depend on “n”. In addition, the photo-sensitizer may further include a conventional photo-sensitizer with the acridine-based compound represented by Chemical Formula 1.

When an amount of the photo-sensitizer is greater than about 0.1 parts by weight with respect to the acrylic based copolymer of about 100 parts by weight, the photosensitivity of the photosensitive composition for UV light having the long wavelength is sufficient to perform a curing reaction of the photosensitive composition. In addition, when the amount of the photo-sensitizer is less than about 30 parts by weight with respect to the acrylic based copolymer of about 100 parts by weight, a resolution of the photosensitive composition may be optimized in a range without changing the properties of the photosensitive composition. Therefore, the amount of the photo-sensitizer may be between about 0.1 parts by weight and about 30 parts by weight with respect to the acrylic based copolymer of about 100 parts by weight. For example, the amount of the photo-sensitizer may be between about 0.5 parts by weight and about 20 parts by is weight.

Solvent

The acrylic based copolymer, the photo-initiator and the photo-sensitizer may be suspended in the solvent. Therefore, a solid content including the acrylic based copolymer, the photo-initiator and the photo-sensitizer may be suspended in the solvent so that the photosensitive composition may have a liquid state or a gel state. The solid content may further include the polyfunctional monomer, the silicon-based compound and/or the surfactant. The solvent planarizes a thin layer when coating the photosensitive composition on a substrate to form the thin layer, and the solvent may control generating a coating stain in a coating process of the photosensitive composition.

Examples of a material that can be used for the solvent include alcohols including methanol, ethanol, etc; ethers including tetrahydrofuran, etc.; glycol ethers including ethylene glycol monomethyl ether, ethylene glycol monoethylether, etc.; ethylene glycol alkyl ether acetates including methyl cellosolve acetate, ethyl cellosolve acetate, etc.; diethylene glycols including diethylene glycol monomethyl ether, diethylene glycol monoethyl ether, or diethylene glycol dimethyl ether, etc.; propylene glycol monoalkyl ethers including propylene glycol methyl ether, propylene glycol ethyl ether, propylene glycol propyl ether, propylene glycol butyl ether, etc.; propylene glycol alkyl ether acetates including propylene glycol methyl ether acetate, propylene glycol ethyl ether acetate, propylene glycol propyl ether acetate, propylene glycol butyl ether acetate, propylene glycol methyl ether propionate, propylene glycol ethyl ether propionate, propylene glycol propyl ether propionate, propylene glycol butyl ether propionate, etc.; aromatic hydrocarbons including toluene, xylene, etc.; ketones including methylethyl ketone, cyclohexanon, or 4-hydroxy 4-methyl 2-pentanone, etc.; or esters including methyl acetate, ethyl acetate, propyl acetate, butyl acetate, 2-hydroxylethyl propionate, 2-hydroxyl 2-methyl propionate, 2-hydroxyl 2-ethyl propionate, hydroxylmethyl acetate, hydroxylethyl acetate, hydroxyl butyl acetate, methyl lactate, ethyl lactate, propyl lactate, butyl lactate, 3-hydroxyl methyl propionate, 3-hydroxylethyl propionate, 3-hydroxylpropyl propionate, 3-hydroxyl butyl propionate, 2-hydroxy 3-methyl butanate, methoxy methyl acetate, methoxy ethyl acetate, methoxy propyl acetate, methoxybutyl acetate, ethoxymethyl acetate, ethoxyethyl acetate, ethoxypropyl acetate, ethoxybutyl acetate, propoxymethyl acetate, propoxyethyl acetate, propoxypropyl acetate, propoxybutyl acetate, butoxymethyl acetate, butoxyethyl acetate, butoxypropyl acetate, butoxybutyl acetate, 2-methoxymethyl propionate, 2-methoxyethyl propionate, 2-methoxypropyl propionate, 2-methoxybutyl propionate, 2-ethoxymethyl propionate, 2-ethoxy ethyl propionate, 2-ethoxypropyl propionate, 2-ethoxybutyl propionate, 2-butoxymethyl propionate, 2-butoxyethyl propionate, 2-butoxypropyl propionate, 2-butoxybutyl propionate, 3-methoxymethyl propionate, 3-methoxyethyl propionate, 3-methoxypropyl propionate, 3-ethoxymethyl propionate, 3-ethoxyethyl propionate, 3-ethoxypropyl propionate, 3-ethoxybutyl propionate, 3-propoxymethyl propionate, 3-propoxyethyl propionate, 3-propoxypropyl propionate, 3-propoxybutyl propionate, 3-butoxymethyl propionate, 3-butoxyethyl propionate, 3-butoxypropyl propionate, 3-butoxybutyl propionate, etc. These may be used alone or as a mixture thereof.

Particularly, the solvent may include glycol ethers, ethylene alkyl ether acetates, or diethylene glycols, etc.

A total weight of the photosensitive composition is a sum of weights of the solid content and the solvent, and when an amount of the solvent is greater than about 50% by weight based on the total weight of the photosensitive composition, the photosensitive composition may be uniformly coated on an entire surface of a substrate and may minimize a damage of a coating device for coating the photosensitive composition. In addition, when the amount of the solvent is less than about 90% by weight, a property of the coating planarization may be optimized. Therefore, the amount of the solvent may be between about 50% by weight and about 90% by weight, and relatively, the amount of the solid content may be between about 10% by weight and about 50% by weight based on the total weight of the photosensitive composition. For example, the photosensitive composition may include about 60% by weight to about 85% by weight of the solvent and about 15% by weight to about 40% by weight of the solid content.

Polyfunctional Monomer

The polyfunctional monomer includes an ethylene unsaturated bond. In particular, the polyfunctional monomer may include a cross-linking monomer having at least two ethylene-based double bonds.

Examples of a material that can be used for the polyfunctional monomer include 1,4-butandiol acrylate, 1,3-butylene glycol diacrylate, ethylene glycol diacrylate, trimethylolpropane diacrylate, trimethylolpropane triacrylate, pentaerythritol triacrylate, pentaerythritol tetraacrylate, triethylene glycol diacrylate, polyethylene glycol diacrylate, dipentaerythritol hexaacrylate, dipentaerythritol triacrylate, dipentaerythritol diacrylate, sorbitol triacrylate, derivatives of bisphenol A diacrylate, dipentaerythritol polyacrylate, or metacylates thereof. These may be used alone or as a mixture thereof.

When an amount of the polyfunctional monomer is greater than about 5 parts by weight with respect to the acrylic based copolymer of about 100 parts by weight, the acrylic based copolymer may easily cross-link with the polyfunctional monomer so that a shape of a thin-film pattern such as a contact hole, etc. formed in a thin layer may be stable. In addition, when the amount of the polyfunctional monomer is less than about 50 parts by weight with respect to the acrylic based copolymer of about 100 parts by weight, curing the photosensitive composition is controlled to improve the resolution of the thin-film pattern in a developing process. Thus, the amount of the polyfunctional monomer may be between about 5 parts by weight and about 50 parts by weight with respect to the acrylic based copolymer of about 100 parts by weight. For example, the amount of the polyfunctional monomer may be between about 10 parts by weight and about 30 parts by weight.

Alternatively, the polyfunctional monomer may be omitted when the acrylic based copolymer includes an unsaturated group having photosensitivity.

Silicon-Based Compound

The silicon-based compound includes an epoxy group or an amine group. Examples of a material that can be used for the silicon-based compound include (3-glycidoxypropyl)trimethoxysilane, (3-glycidoxypropyl)triethoxysilane, (3-glycidoxypropyl)methyldimethoxysilane, (3-glycidoxypropyl)dimethylethoxysilane, 3,4-epoxybutyltrimethoxysilane, 3,4-epoxybutyltriethoxysilane, 2-(3,4-epoxy cyclohexyl)ethyltrimethoxysilane, 2-(3,4-epoxy cyclohexyl)ethyltriethoxysilane, aminopropyl trimethoxy silane, etc. These may be used alone or as a mixture thereof.

When an amount of the silicon-based compound is greater than about 0.0001 parts by weight with respect to the acrylic based copolymer of about 100 parts by weight, an adhesive strength between a layer formed from the photosensitive composition and a layer including indium oxide, for example, indium tin oxide (ITO) may be improved. In addition, a heat-resisting property for heat curing of the layer formed from the photosensitive composition may be improved. When the amount of the silicon-based compound is less than about 5 parts by weight with respect to the acrylic based copolymer of about 100 parts by weight, a non-exposed region of the layer formed from the photosensitive composition, in which light is not irradiated in an exposing process, is prevented from being whitened by a developing solution in a developing process or from generating a scum after being developing. Thus, the amount of the silicon-based compound may be between about 0.0001 parts by weight and about 5 parts by weight with respect to the acrylic based copolymer of about 100 parts by weight.

Surfactant

The surfactant may improve a coating property and/or a developing property of the photosensitive composition. Examples of a material that can be used for the surfactant include polyoxyethylene octylphenyl ether, polyoxy ethylene nonyl phenylether, F171, F172, F173 (product name, Dainippon ink & chemicals, Japan), FC430, FC431 (product name, Sumitomo 3M® company, Japan), KP341 (product name, Shinetsu chemical company, Japan), etc. These may be used alone or as a mixture thereof.

When an amount of the surfactant is greater than about 0.0001 parts by weight with respect to the acrylic based copolymer of about 100 parts by weight, the photosensitive composition may be uniformly coated to improve a reliability of coating. When the amount of surfactant is less than about 2 parts by weight with respect to the acrylic based copolymer of about 100 parts by weight, generating bubbles in a coating process of the photosensitive composition may be suppressed so that decreasing a reliability of forming a thin layer may be prevented. Thus, the amount of the surfactant may be between about 0.0001 parts by weight and about 2 parts by weight with respect to the acrylic based copolymer.

Additives

The photosensitive composition may further include additives such as a thermo polymerization inhibitor, a defoaming agent, etc. In addition, the photosensitive composition may further include a pigment and/or a dye having a color.

According to the above descriptions, a light-transmittance, a resolution, an adhesive strength, and a heat discoloration resistance, etc. of the photosensitive composition may be improved, and a photosensitivity to UV light having a wavelength greater than about 365 nm may be improved. Thus, a display quality may be improved. In particular, the photosensitive composition may be used for forming a photoresist layer using a digital exposure device which uses UV light having a wavelength greater than about 365 nm. The photosensitive layer may be an organic insulating layer protecting a thin-film transistor, a spacer or a color filter, etc., and the photosensitive layer may be used for an etch stopping layer which is removed after being used in forming the thin-film transistor.

Hereinafter, the photosensitive composition according to exemplary embodiments of the present invention will be described in detail referring to Examples and Comparative Examples. These Examples and Comparative Examples are exemplary embodiments for illustrative purposes and are not intended to be limiting to these embodiments.

### Composite Example 1

### Preparing an Acrylic Based Copolymer

A first mixed solution including propyleneglycolmonoethyl acetate of about 400 parts by weight, methacrylic acid of about 300 parts by weight, styrene of about 30 parts by weight and aryl methacrylate of about 40 parts by weight was added to a flask prepared with a radiator and an agitator and the first mixed solution was mixed at about 600 rpm. After fully mixing, 2,2′-azobis(2,4-dimethylvaleronitrile) of about 15 parts by weight was added in the first mixed solution to form a second mixed solution. A temperature of the second mixed solution was slowly increased until reaching about 70° C. and held at about 70° C. for about 8 hours, and then the second mixture was cooled and hydrobenzophenone as a polymerization inhibitor of about 500 ppm was added, thereby obtaining an acrylic based copolymer with a concentration of a solid content of about 20% by weight. A weight-average molecular weight of the acrylic based copolymer obtained was about 10,000. The weight-average molecular weight is based on a polystyrene-reduced weight-average molecular weight being measured by a GPC.

### Example 1

The acrylic based copolymer prepared according to the above Composite Example 1 of about 100 parts by weight, [1-[9-ethyl-6-(2-methylbenzoyl)-9H-carbazoyl-3-yl]-1-(o-acetyloxime) as a photo-initiator of about 5 parts by weight, 10-butyl-10H-acridine-9-on as a photo-sensitizer of about 3 parts by weight, dipentaerythritol hexaacrylate and trimethylolpropane triacrylate as a polyfunctional monomer of about 10 parts by weight were mixed. After propylene glycol monoethyl acetate as a solvent was added to the mixed compounds so that a concentration of a solid content was about 20% by weight in suspension, the suspension of the solvent and the mixed compounds was filtered using a millipore filter to prepare a photosensitive composition according to Example 1.

### Example 2

A photosensitive composition according to Example 2 was prepared by the same method as the photosensitive composition according to Example 1 except for using 2-(o-chlorophenyl)-4,5-di(m-methoxyphenyl)imidazole dimmer (HABI-1311 (product name), Daerim Chemical corporation, Korea) as the photo-initiator in place of [1-[9-ethyl-6-(2-methylbenzoyl)-9H-carbazoyl-3-yl]-1-(o-acetyloxime).

### Example 3

A photosensitive composition according to Example 3 was prepared by the same method as the photosensitive composition according to Example 1 except for using Irgacure819 (product name, Ciba® specialty chemical corporation, Swiss) having a chemical structure of bis(2,4,6-trimethylbenzoyl)-phenylphosphineoxide, as the photo-initiator in place of [1-[9-ethyl-6-(2-methylbenzoyl)-9H-carbazoyl-3-yl]-1-(o-acetyloxime).

### Example 4

A photosensitive composition according to Example 4 was prepared by the same method as the photosensitive composition according to Example 1 except for using 10-propyl-10H-acridine-9-on as the photo-sensitizer in place of 10-butyl-10H-acridine-9-on.

### Example 5

A photosensitive composition according to Example 5 was prepared by the same method as the photosensitive composition according to Example 1 except for using 10-propyl-10H-acridine-9-on as the photo-sensitizer in place of about 3 parts by weight of 10-butyl-10H-acridine-9-on.

### Comparative Example 1

A photosensitive composition according to Comparative Example 1 was prepared by the same method as the photosensitive composition according to Example 1 except for omitting the photo-sensitizer.

### Comparative Example 2

A photosensitive composition according to Comparative Example 2 was prepared by the same method as the photosensitive composition according to Example 1 except for using 2-isopropylthioxanthone as the photo-sensitizer in place of 10-butyl-10H-acridine-9-on.

### Comparative Example 3

A photosensitive composition according to Comparative Example 3 was prepared by the same method as the photosensitive composition according to Example 1 except for using 2,4-diethylthioxanthone in place of 10-butyl-10H-acridine-9-on.

Manufacturing Samples and Comparative Samples

The photosensitive composition according to Example 1 was coated by using a spin coater on a glass substrate on which a silicon nitride (SiNₓ) layer was formed, thereby forming a coating layer. The coating layer was pre-baked on a hot plate at a temperature of about 100° C. for about 2 minutes to form a photosensitive layer having a thickness of about 4 μm. A pattern mask was disposed over the photosensitive layer and UV light having an intensity of about 10 mW/cm² at about 405 nm was irradiated to the photosensitive layer for about 30 seconds at an interval of about 1 second. Then, the photosensitive layer was developed by an aqueous solution including tetramethyl amoniumhydroxide of about 2.38% by weight at a temperature of about 23° C. for about 2 minutes and washed using deionized water for about 1 minute. The photosensitive layer developed was heated in an oven at a temperature of about 220° C., for about 60 minutes to obtain Sample 1 including a photosensitive pattern.

In addition, Samples 2 to 5 and Comparative Samples 1 to 3 were prepared using each of the photosensitive compositions according to Examples 2 to 5 and Comparative Examples 1 to 3 by substantially the same method as manufacturing Sample 1.

Evaluation of Properties of the Photosensitive Patterns

Properties for each of Samples 1 to 5 and Comparative Samples 1 to 3 were evaluated by the following methods, and the thusly obtained results are illustrated in Table 1.

1) Photosensitivity

A photosensitivity of each of Samples 1 to 5 and Comparative Samples 1 to 3 was measured using a scanning electron microscope (“SEM”) with respect to an exposure intensity which a ratio of residues was saturated with respected to a line of about 20 μm and a space critical dimension (“space CD”).

2) Resolution

A minimum attainable feature size of each of the photosensitive patterns in Samples 1 to 5 and Comparative Samples 1 to 3 was measured.

3) Adhesive Strength

A minimum thickness of each of the photosensitive patterns in Sample 1 to 5 and Comparative Samples 1 to 3 was measured. In Table 1, “∘” represents that the minimum thickness is less than about 1.2 μm, “Δ” represents that the minimum thickness is between about 1.2 μm and about 1.8 μm, and “x” represents that the minimum thickness is greater than about 1.8 μm.

4) Light Transmittance

A Light transmittance of each of the photosensitive patterns in Samples 1 to 5 and Comparative Samples 1 to 3 was measured using a spectrophotometer at a wavelength of about 400 nm. In Table 1, “∘” represents that the light transmittance is greater than about 90%, “Δ” represents that the light transmittance is between about 85% and 90%, and “x” represents that the light transmittance is less than about 80%.

5) Heat Discoloration Resistance

After Samples 1 to 5 and Comparative Samples 1 to 3 were cured in an oven at a temperature of about 300° C. for about 40 minutes, a light transmittance of each of the photosensitive patterns of Samples 1 to 5 and Comparative Samples 1 to 3 was measured using the spectrophotometer at a wavelength of about 400 nm. Differences between the light transmittance measured after curing and the light transmittance before curing were calculated to evaluate a heat discoloration resistance. In Table 1, “∘” represents that the difference is less than about 5%, “Δ” represents that the difference is between about 5% and about 10%, and “x” represents that the difference is greater than about 10%.

TABLE 1

| | | | | | Heat |
|---|---|---|---|---|---|
| | Photo- | | | Light | dis- |
| | sensitivity | Resolution | Adhesive | trans- | coloration |
| | (mJ/cm²) | (μm) | strength | mittance | resistance |
| Sample 1 | 40 | 3 | ∘ | ∘ | ∘ |
| Sample 2 | 40 | 3 | ∘ | ∘ | ∘ |
| Sample 3 | 40 | 3 | ∘ | ∘ | ∘ |
| Sample 4 | 41 | 3 | ∘ | ∘ | ∘ |
| Sample 5 | 35 | 3 | ∘ | ∘ | ∘ |
| Comparative | A photosensitive pattern is not formed. | | | | |
| Sample 1 | | | | | |
| Comparative | 200 | 8 | ∘ | ∘ | ∘ |
| Sample 2 | | | | | |
| Comparative | 200 | 8 | ∘ | ∘ | ∘ |
| Sample 3 | | | | | |

Referring to Table 1, each of the adhesive strength, the light-transmittance, and the heat discoloration resistance of Samples 1 to 5 formed using the photosensitive compositions according to Examples 1 to 5 is excellent being substantially equal to the adhesive strength, the light-transmittance, and the heat discoloration resistance of Comparative Samples 1 to 3. Although the photosensitive compositions according to Examples 1 to 5 include the photo-sensitizer, the adhesive strength, the light-transmittance and the heat discoloration resistance are not decreased and the excellent properties maintain.

Particularly, the photosensitivity of each of the photosensitive compositions according to Examples 1 to 5 is extraordinarily excellent compared to the photosensitive compositions according to Comparative Examples 1 to 3. In addition, the resolution of the photosensitive compositions according to Examples 1 to 5 is extraordinarily excellent compared to the photosensitive compositions according to Comparative Examples 1 to 3. Since the photosensitivity and the resolution are measured in irradiating a light having a wavelength of about 405 nm, it may be advantageous when a thin layer or a pattern is formed using a digital exposure device which uses an ultra violet light having a long wavelength of about 405 nm.

Method of Manufacturing a Display Substrate

Hereinafter, a method of manufacturing a display substrate using the photosensitive composition according to exemplary embodiments of the present invention will be explained in detail with reference to the accompanying drawings.

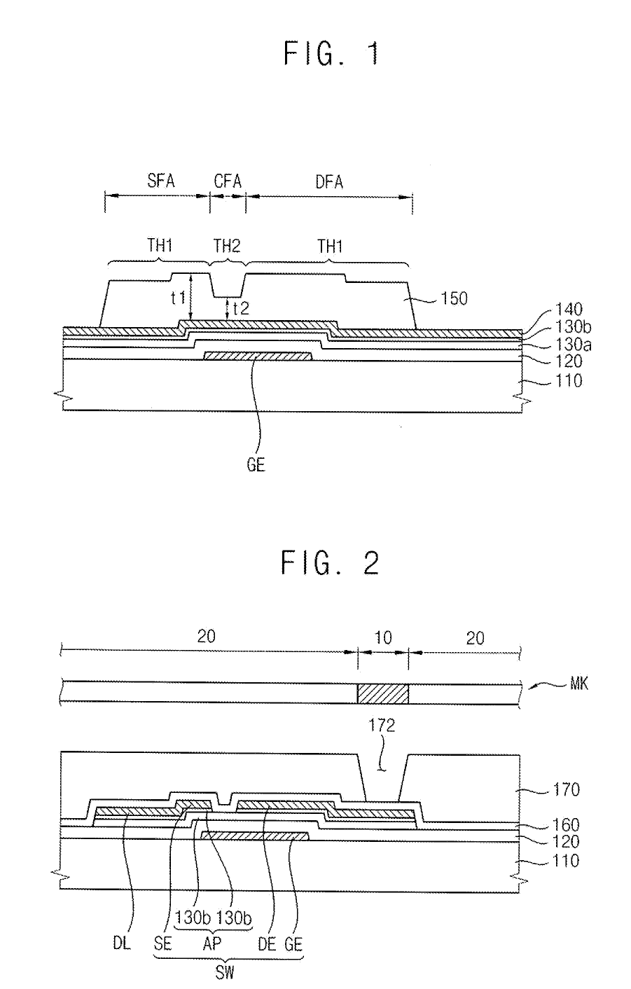

FIGS. 1 to 3 are cross-sectional views illustrating a method of manufacturing a display substrate according to an exemplary embodiment of the present invention.

Referring to FIG. 1, a gate pattern including a gate electrode GE and a gate line (not shown) connected to the gate electrode GE is formed on a base substrate 110. The gate pattern may be a single layer conductor or a multilayer conductor (not shown) of copper, aluminum, titanium, alloys thereof, and the like.

A gate insulating layer 120, a semiconductor layer 130a, an ohmic contact layer 130b and a source metal layer 140 are continuously formed on the base substrate 110 on which the gate pattern is formed. The gate insulating layer 120 may include a silicon nitride and the like. The semiconductor layer 130a may include amorphous silicon and the like, and the ohmic contact layer 130b may include amorphous silicon doped with n-type dopants at a high concentration and the like. The source metal layer 140 may be a single layer conductor or a multilayer conductor (not shown) of copper, aluminum, titanium, alloys thereof, and the like.

A photo pattern 150 is formed on the base substrate 110 on which the source metal layer 140 is formed. The photo pattern 150 includes a first thickness portion TH1 formed in a first electrode-formation region SFA and a second electrode-formation region DFA spaced apart from each other and a second thickness portion TH2 formed in a channel-formation region CFA. A first thickness t₁ of the first thickness portion TH1 is greater than a second thickness t₂ of the second thickness portion TH2. The photo pattern 150 may be formed from a photoresist composition of a negative type remained in an exposed region or a photoresist composition of a positive type removed in the exposed region, that is, a positive type remained in the unexposed region.

The source metal layer 140, the semiconductor layer 130a and the ohmic contact layer 130b are etched using the photo pattern 150 as an etch stopping layer. The source metal layer 140, the semiconductor layer 130a and the ohmic contact layer 130b are first etched, and the second thickness portion TH2 is removed in an etch-back process of the photo pattern 150. The source metal layer 140 and the ohmic contact layer 130b are second etched using the photo-pattern 150 remained after removing the second thickness portion TH2 as an etch stopping layer.

Referring to FIG. 2, a source electrode SE, a drain electrode DE and an active pattern AP are formed on the gate insulating layer 120. The source electrode SE and a data line DL connected to the source electrode SE are formed in the first electrode-formation region SFA and the drain electrode DE is formed in the second electrode-formation region DFA. The source electrode SE and the drain electrode DE are spaced apart from each other by the channel-formation region CFA. The semiconductor layer 130a of the active pattern AP in the channel-formation region CFA is exposed. Thus, a thin-film transistor SW including the gate electrode GE, the source electrode SE, the drain electrode DE and the active pattern AP is formed. The photo pattern 150 is removed by a stripper after used in forming the source electrode SE, the drain electrode DE and the active pattern AP.

Then, a passivation layer 160 and an organic insulating layer 170 are formed on the base substrate 110 on which the thin-film transistor SW is formed. The passivation layer 160 may include silicon nitride, silicon oxide or the like. The organic insulating layer 170 is a photoresist layer formed from a photosensitive composition. The photosensitive composition includes an acrylic based copolymer, a photo-initiator, a photo-sensitizer represented by Chemical Formula 1, and a solvent.

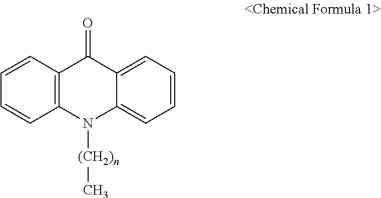

In Chemical Formula 1, “n” represents an integer in a range of 1 to 10.

The photosensitive composition is substantially the same as the photosensitive composition according to the exemplary embodiments of the present invention illustrated above, and thus any further repetitive and detailed description will be omitted here.

The photosensitive composition is coated on the base substrate 110 on which the passivation layer 160 is formed. The photosensitive composition may be coated on the base substrate 110 by a sprayed method, a roll-coater method, a spin coating method, etc. The photosensitive composition coated on the base substrate 110 is pre-baked to remove the solvent, thereby forming a coating layer on the passivation layer 160. The pre-baking process may be performed between about 1 minute and about 15 minutes at a temperature between about 70° C. and about 110° C.

A mask MK is disposed over the coating layer and a light is irradiated from an upside of the mask MK toward the coating layer. The light may be UV light having a wavelength of about 405 nm. The mask MK includes a light-blocking part 10 blocking the light and a light-transmittance part 20 transmitting the light.

Since the light is not irradiated to the coating layer corresponding to the light-blocking part 10, the coating layer corresponding to the light-blocking part 10 is removed in a developing process by a developing solution. In addition, the light is irradiated to the coating layer corresponding to the light-transmittance part 20 so that the coating layer is cured. Thus, the coating layer corresponding to the light-transmittance part 20 is not removed by the developing solution and remains on the passivation layer 160.

The developing solution may include an alkali aqueous solution. Examples of a material that can be used for the developing solution include inorganic alkalis including sodium hydroxide, potassium hydroxide, sodium carbonate, etc.; first amines including n-propyl amine; second amines including diethyl amine, n-propylamine, etc.; third amines including trimethyl amine, methyldiethyl amine, dimethylethyl amine, triethyl amine, etc.; alcohol amines including dimethylethanol amine, methyldiethanol amine, triethanol amine, etc.; or a solution of a fourth ammonium salt including tetramethylammoniumhydroxide, tetraethylammoniumhydroxide, etc. These may be used alone or a mixture thereof. Then, the developing solution may include an alkali compound between about 0.1% by weight and about 10% by weight based on a total weight of the developing solution. The developing solution may further include an organic solvent of water solubility including methanol, ethanol, etc and/or a surfactant.

After developing, the coating layer is washed by deionized water for about 30 seconds to about 90 seconds so that an unnecessary portion of the coating layer is removed, and the coating layer is dried. After irradiating light such as UV light, developing, etc., the coating layer is heated using a heating device, for example, an oven, at a temperature between about 150° C. and about 250° C. for about 30 minutes to about 90 minutes, thereby forming the organic insulating layer 170. The organic insulating layer 170 is a photoresist layer remaining on the base substrate 110 after manufacturing the display substrate. The coating layer corresponding to the light-transmittance part 20 remains on the base substrate 110 to be substantially the organic insulating layer 170, and the coating layer corresponding to the light-blocking part 10 has been removed to form a first hole 172 in the organic insulating layer 170. The passivation layer 160 is partially exposed through the first hole 172.

Referring to FIG. 3, the passivation layer 160 is etched using the organic insulating layer 170 in which the first hole 172 is formed as an etch stopping layer, so that a second hole 162 corresponding to the first hole 172 is formed in the passivation layer 160. The first and second holes 172 and 162 define a contact hole CNT partially exposing the drain electrode DE.

A transparent layer is formed on the base substrate 110 on which the contact hole CNT is formed, and the transparent layer is patterned to form a pixel electrode PE. The pixel electrode PE may include an indium oxide. For example, the pixel electrode PE may include indium tin oxide (ITO) or indium zinc oxide (IZO). The pixel electrode PE directly makes contact with the drain electrode DE through the contact hole CNT. The organic insulating layer 170 is formed from the photosensitive composition, and thus the pixel electrode PE may be stably formed on the organic insulating layer 170.

According to the above descriptions, although light having a wavelength of about 405 nm is used in an exposing process of forming the organic insulating layer 170, the organic insulating layer 170 includes the photosensitive composition so that the organic insulating layer 170 may be easily formed since the photosensitivity of the photosensitive composition for light of that wavelength is good. In addition, an adhesive strength between the organic insulating layer 170 and the pixel electrode PE may be improved by the photosensitive composition.

Although the photosensitive composition is used for forming the organic insulating layer 170 in FIGS. 2 and 3, the photo pattern 150 in FIG. 1 may be formed from the photosensitive composition. Since the photosensitive composition has good photosensitivity for light, a profile of the first and second thickness portions TH1 and TH2 of the photo pattern 150 may be stabilized. A reliability of the photo pattern 150 may be improved, thereby improving a reliability of forming the source electrode SE, the drain electrode DE and the active pattern AP.

In addition, the photosensitive composition may be used for forming a photo pattern in forming the gate pattern or for patterning the transparent electrode layer in forming the pixel electrode PE.

The photosensitive composition may further include a coloring agent to represent a color. When the photosensitive composition further includes the coloring agent, the organic insulating layer 170 may be a color filter of the display substrate.

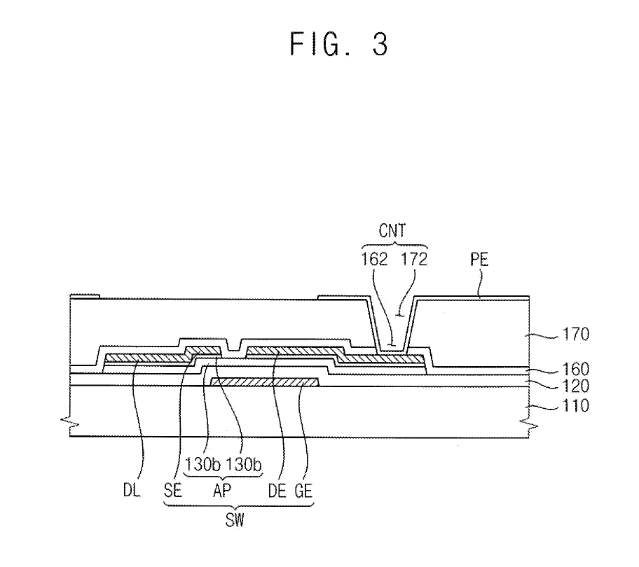

FIG. 4 is a conceptual view illustrating a digital exposure device used for manufacturing a display substrate according to another exemplary embodiment of the present invention.

A method of manufacturing a display substrate according to this exemplary embodiment of the present invention is substantially the same as the method illustrated in FIGS. 1 to 3 except that the mask MK is not used for forming the organic insulating layer 170. Thus, the method of manufacturing the display substrate according to this exemplary embodiment of the present invention will be illustrated referring to FIGS. 1 to 3 and any further repetitive descriptions will be omitted here.

Referring to FIGS. 1 and 2, in order to manufacture a display substrate, a passivation layer 160 and an organic insulating layer 170 are formed on a base substrate 110 on which a thin-film transistor SW is formed.

The organic insulating layer 170 is formed from a photosensitive composition including an acrylic based copolymer, a photo-initiator, a photo-sensitizer represented by Chemical Formula 1, and a solvent.

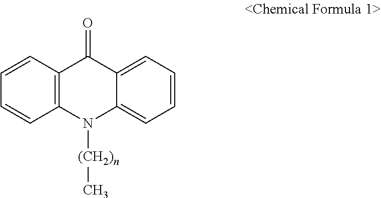

In Chemical Formula 1, “n” represents an integer in a range of 1 to 10.

A coating layer is formed using the photosensitive composition. The coating layer is exposed and developed, and a washing process and a post-baking process are performed to form the organic insulating layer 170 including a first hole 172. Processes forming the organic insulating layer 170 except for using a digital exposure device with the mask MK shown in FIG. 2 in the exposing process are substantially the same as illustrated in FIGS. 2 and 3. Thus, any further repetitive descriptions will be omitted here. Hereinafter, the digital exposure device will be shortly illustrated referring to FIG. 4.

Referring to FIG. 4, the digital exposure device 400 includes a light source 200 generating light, an optical head 300 receiving light from the light source 200, and a stage 340 receiving light from the optical head 300.

The light source 200 emits a laser beam to the optical head 300.

The optical head 300 includes a beam splitter 310, a digital micro-minor device (“DMD”) 320, and an optical system 330. In particular, the beam splitter 310 may reflect and transmit the laser beam emitted from the light source 200. The laser beam reflected by the beam splitter 310 is provided to the DMD 320. The beam splitter 310 transmits a light received from the DMD 320 to provide the light to the optical system 330.

The DMD 320 includes a plurality of micro-minors 322. The micro-mirrors 322 may be arranged having a matrix shape of m×n. Each of the micro-mirrors 322 may reflect the light received from the beam splitter 310. The DMD 320 may selectively reflect the light received from the beam splitter 310 based on image data forming an image provided onto a substrate SUB disposed on the stage 340. Although not shown in figures, the optical head 300 may further include a mirror controlling part controlling each of the micro-minors 322 based on the image data. The minor controlling part may output a signal controlling turning on or off the micro-minors 322. When the micro-minors 322 receive activate data, the number of reflected beams provided to the optical system 330 is substantially the same as the number of the micro-minors 322.

The optical system 330 includes a plurality of lenses. The optical system 330 transforms the reflected beams provided from the DMD 320 into a plurality of spot beams SB. The optical system 330 concentrates the reflected beams emitted from the DMD 320 and increases a distance between the reflected beams.

The digital exposure device irradiates the spot beams SB onto the substrate SUB disposed on the stage 340 so that a photosensitive layer (not shown) formed on the substrate SUB is exposed. Hereinafter, “exposing the substrate SUB” is defined to be substantially the same as exposing the base substrate 110 on which the coating layer formed on the passivation layer 160 is formed.

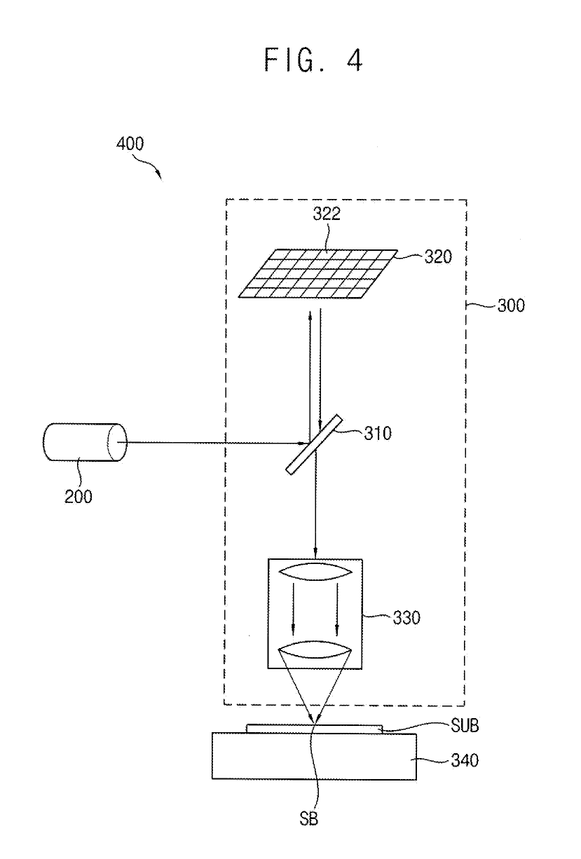

FIG. 5 is a plan view illustrating an exposure step using the digital exposure device in FIG. 4.

Referring to FIGS. 4 and 5, the substrate SUB is exposed by the spot beams SB.

For example, the DMD 320 is fixed to be inclined by a predetermined angle θ with respect to the substrate SUB in order to expose a line or an area extending in a second direction D2 perpendicular to a first direction D1 as a scanning direction MD. Thus, the substrate SUB and the DMD 320 are disposed inclined along a third direction D3.

The substrate SUB is moved along the scanning direction MD when the DMD 320 is fixed in a predetermined region, so that the spot beams SB are irradiated in the predetermined region with overlapping with each other as time passes. The spot beams SB are selectively irradiated to the substrate SUB by turning on/off the micro-minors 322.

For example, the micro-minors 322 corresponding to a non-exposed region receive an inactivate data and the micro-minors 322 corresponding to an exposed region receive an activate data.

For example, the micro-minors 322 corresponding to the non-exposed region receive inactivate data and the micro-mirrors 322 corresponding to the exposed region receive activate data. When the micro-minors 322 receive the inactivate data, the spot beams SB are not irradiated to the substrate SUB. For the sake of convenient reference, when the micro-mirrors 322 receive inactivate data and are disposed in the non-exposed region, is expressed by “,” and this refers to a “light-blocking point.” In addition, when the micro-mirrors 322 receive the activate data and are disposed in the exposed region, is expressed by “∘,” and this refers an “exposed point.”

Referring to FIG. 5 with FIG. 3, in order to form a first hole 172 of the organic insulating layer 170, a contact hole-formed region CNTA is determined to be the non-exposed region and the rest of the region excluding the contact hole-formed region CNTA is determined to be the exposed region, and the activate or the inactivate data are provided to each of the corresponding micro-mirrors 322.

When the micro-mirrors 322 are disposed in the contact hole-formed region CNTA, the micro-mirrors 322 receive the inactivate data to define a light-blocking point A11 on the substrate SUB. In contrast, when the micro-mirrors 322 are disposed in the rest of the region, the micro-mirrors 322 receive the activate data to irradiate the spot beam SB, thereby defining an exposed point A12 of the substrate SUB. The substrate SUB is moved along the scanning direction MD, so that the micro-minors 322 defining the exposed point A12 in the rest of the region of a previous step are disposed in the contact hole-formed region CNTA. Thus, the micro-minors 322 defining the exposed point A12 in the previous step receive the inactivate data to define a light-blocking point A11 of the substrate SUB after the substrate SUB is moved along the scanning direction MD. Similarly, the substrate SUB is moved along the scanning direction MD, so that the micro-mirrors 322 defining the light-blocking point A11 in the contact hole-formed region CNTA of a previous step are disposed in the rest of the region. Thus, the micro-mirrors 322 defining the light-blocking point A11 in the previous step receive the activate data to define a exposed point A12 of the substrate SUB after the substrate SUB is moved along the scanning direction MD.

Through the above processes, the spot beams SB are not irradiated to the contact hole-formed region CNTA and are irradiated to the rest of the region to be exposed. The coating layer exposed by the digital exposure device is developed to form the first hole 172 shown in FIG. 2 in the contact hole-formed region CNTA.

Although not shown in figures, the digital exposure device shown in FIG. 4 may be used when the photosensitive composition is used for forming a gate electrode GE of the thin-film transistor, for forming the photo pattern 150 shown in FIG. 1, and for the pixel electrode PE shown in FIG. 3.

According to the above descriptions of the exemplary embodiments, although light having a wavelength of about 405 nm is used in an exposing process of forming the organic insulating layer 170, the organic insulating layer 170 includes the photosensitive composition so that the organic insulating layer 170 may be easily formed since the photosensitivity of the photosensitive composition for light of that wavelength is good.

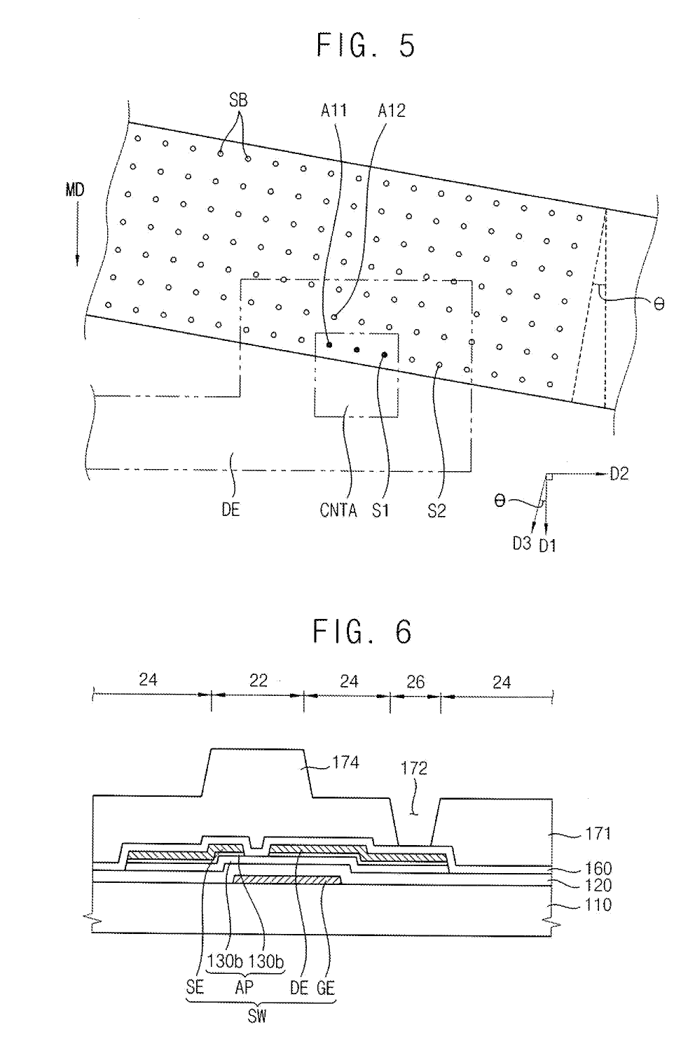

FIG. 6 is a cross-sectional view illustrating a method of manufacturing a display substrate according to still another exemplary embodiment of the present invention.

Referring to FIG. 6, a thin-film transistor SW is formed on a base substrate 110, and a passivation layer 160 is formed on the thin-film transistor SW. Processes forming the thin-film transistor SW, a gate insulating layer 120 and the passivation layer 160 are substantially the same as illustrated referring FIGS. 1 and 2. Thus, any further repetitive descriptions will be omitted here.

A coating layer is formed using a photosensitive composition on the passivation layer 160 and is exposed and developed to form an organic insulating layer 171 including a first hole 172. The photosensitive composition includes an acrylic based copolymer, a photo-initiator, a photo-sensitizer represented by Chemical Formula 1, and a solvent.

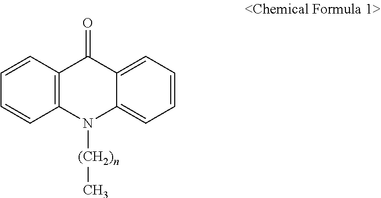

In Chemical Formula 1, “n” represents an integer in a range of 1 to 10.

The photosensitive composition is substantially the same as the photosensitive composition of the exemplary embodiments of the present invention illustrated above, and thus any further repetitive descriptions thereof will be omitted here.

An initial thickness of the coating layer is greater than a thickness of the organic insulating layer 170 shown in FIG. 2. The coating layer is exposed using the digital exposure device shown in FIG. 4. In order to be exposed by the digital exposure device, the base substrate 110 may be divided to a first exposed region 22, a second exposed region 24 and a light-blocking region 26. When a light intensity of the first exposed region 22 is defined as “1,” a light intensity of the second exposed region 24 may be less than 1 and greater than 0, and a light intensity of the light-blocking region 26 may be 0. The light intensity of each of the first exposed region 22, the second exposed region 24 and the light-blocking region 26 may be determined by adjusting activate or inactivate data of the micro-mirrors 322 of the digital exposure device.

After developing, a thickness of the coating layer remained in the first exposed region 22 is similar to the initial thickness of the coating layer, and the coating layer in the second exposed region 24 is partially removed and partially remained to be a thickness portion thinner than the first exposure region 22. In addition, the coating layer corresponding to the light-blocking region 26 is removed by a developing solution to form the first hole 172. Thus, the organic insulating layer 171 includes the first hole 172 and a spacer portion 174 corresponding to the first exposed region 22. The spacer portion 174 may be a member to maintain a cell gap which constantly maintains a gap between the display substrate and an opposite substrate to the display substrate. For example, the spacer portion 174 is disposed on the thin-film transistor SW.

According to the above descriptions, although light having a wavelength of about 405 nm in an exposing process of forming the organic insulating layer 171, the organic insulating layer 171 includes the photosensitive composition so that the organic insulating layer 171 may be easily formed since the photosensitivity of the photosensitive composition for light of that wavelength is good.

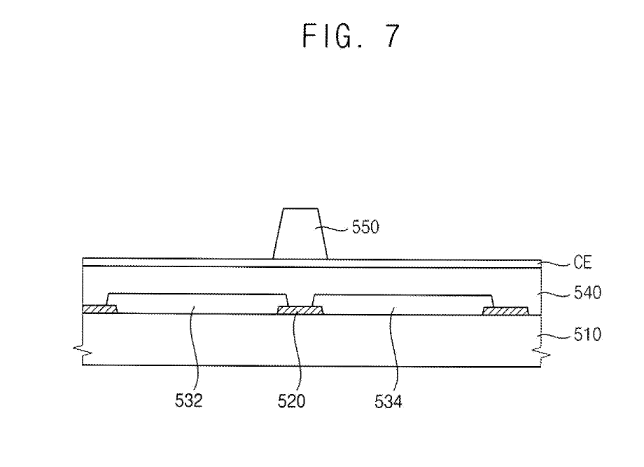

FIG. 7 is a cross-sectional view illustrating a method of manufacturing a color filter substrate according to further still another exemplary embodiment of the present invention.

Referring to FIG. 7, a light-blocking pattern 520 is formed on a base substrate 510. When viewed in a plan view (not shown), the light-blocking pattern 520 is formed at boundaries of opening portions arranged in a matrix shape. For example, the light-blocking pattern 520 includes a first stripe pattern extending in a direction and a second stripe pattern crossing the first stripe pattern to have a reticulated shape.

A first color filter 532 is formed using a first photosensitive composition including an acrylic based copolymer, a photo-initiator, a photo-sensitizer represented by Chemical Formula 1, and a solvent on the base substrate 510 on which the light-blocking pattern 520 is formed.

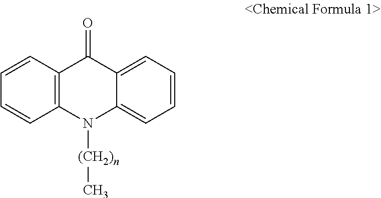

In Chemical Formula 1, “n” represents an integer in a range of 1 to 10. The acrylic based copolymer, the photo-initiator, the photo-sensitizer and the solvent of the first photosensitive composition are substantially the same as those of the photosensitive composition of the exemplary embodiments of the present invention illustrated above, and thus any further repetitive descriptions will be omitted here. The first photosensitive composition further includes the pigment and/or the dye to express green, red or blue color.

Processes coating, exposing and developing the first photosensitive composition are substantially the same as illustrated in FIG. 2 except that an exposure region is an opening portion divided by the light-blocking pattern 520, and thus any further repetitive descriptions will be omitted here. The first photosensitive composition is coated, exposed and developed to form the first color filter 532. For example, the first color filter 532 may represent red. In the exposing process exposing a coating layer including the first photosensitive composition, a mask or a digital exposure device may be used.

A second photosensitive composition different from the first photosensitive composition is coated, exposed and developed to form a second color filter 534 on the base substrate 510 on which the first color filter 532 is formed. The second photosensitive composition is substantially the same as the first photosensitive composition except for a color of the pigment and/or the dye. Thus, any further repetitive descriptions will be omitted here. For example, the second color filter 534 may represent green. In the exposing process exposing a coating layer including the second photosensitive composition, a mask or a digital exposure device may be used.

Although not shown in the figures, a third color filter may be formed after forming the first and second color filters 532 and 534. The third color filter may be formed from a photosensitive composition including a pigment and/or a dye expressing blue color. Although the first color filter 532, the second color filter 534 and the third color filter (not shown) are described as formed sequentially, they may be formed in any order or simultaneously according to various different exemplary embodiments.

An over-coating layer 540 is formed on the base substrate 510 on which the first and second color filters 532 and 534 and the third color filter are formed. The over-coating layer 540 may be formed from a photosensitive composition including an acrylic based copolymer, a photo-initiator, a photo-sensitizer represented by Chemical Formula 1, and a solvent. The photosensitive composition forming the over-coating layer 540 is substantially the same as the photosensitive composition of the above described exemplary embodiments of the present invention, and thus any further repetitive descriptions will be omitted here. An exposing process forming the over-coating layer 540 may use a mask or a digital exposure device.

A common electrode CE is formed on the base substrate 510 on which the over-coating layer 540 is formed. The common electrode CE may be formed from substantially the same material as the pixel electrode PE. Thus, the over-coating layer 540 is formed from the photosensitive composition so that an adhesive strength between the over coating layer 540 and the common electrode CE may be improved.

A spacer 550 is formed on the base substrate 510 on which the common electrode CE is formed. A coating layer is formed from a photosensitive composition including an acrylic based copolymer, a photo-initiator, a photo-sensitizer represented by Chemical Formula 1, and a solvent and is exposed and developed to form the spacer 550. The exposing process of the coating layer may use a mask or a digital exposure device. A light is irradiated to a region corresponding to the spacer 550, and the rest of the region excluding the region corresponding to the spacer 550 is light-blocked to form the spacer 550.

According to the above descriptions, the photosensitive composition forming each of the first color filter 532, the second color filter 534, the third color filter (not shown), the over-coating layer 540 and the spacer 550 includes the acrylic based copolymer, the photo-initiator, the photo-sensitizer, and the solvent in common, so that the over-coating layer 540 and the spacer 550 may be easily formed since the photosensitivity of the photosensitive composition for light is good, although light having a wavelength of about 405 nm is irradiated to the photosensitive composition.

As described above in detail, a light-transmittance, a resolution, an adhesive strength, and a heat discoloration resistance, etc. of a photosensitive composition may be improved, and a photosensitivity of light excluding a wavelength of about 365 nm may be improved. Therefore, a thin-film pattern may be formed from the photosensitive composition using a digital exposure device which uses a light source generating UV light having a longer wavelength than about 365 nm and a reliability of forming the thin-film pattern may be improved.

The photosensitivity of the photosensitive composition for the digital exposure device may be improved, thereby decreasing an exposure time of forming the thin-film pattern, thereby improving productivity. In addition, the light-transmittance, the resolution, the adhesive strength, and the heat discoloration resistance may be improved, thereby improving a display quality.

The foregoing is illustrative and exemplary of the present invention and is not to be construed as limiting thereof. Although a few exemplary embodiments of the present invention have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims and their equivalents. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific exemplary embodiments disclosed, and that modifications to the disclosed exemplary embodiments, as well as other exemplary embodiments without departing from the spirit or scope of the invention, are intended to be included within the scope of the appended claims. The present invention is defined by the following claims, with equivalents of the claims to be included therein.

What is claimed is:

1. A photosensitive composition, comprising:
an acrylic based copolymer;
a photo-initiator;
a photo-sensitizer represented by Chemical Formula 1; and
a solvent, 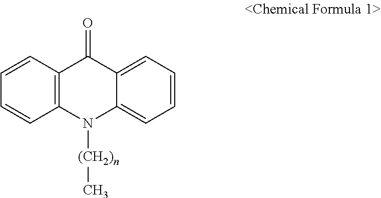
wherein 1≦n≦10.

2. The photosensitive composition of claim 1, wherein an amount of the photo-sensitizer is between about 0.1 parts by weight and about 30 parts by weight with respect to the acrylic based copolymer of about 100 parts by weight.

3. The photosensitive composition of claim 1, wherein the photo-sensitizer absorbs light having a wavelength between about 400 nm and about 410 nm.

4. The photosensitive composition of claim 1, wherein an amount of the photo-initiator is between about 0.1 parts by weight and about 30 parts by weight with respect to the acrylic based copolymer of about 100 parts by weight.

5. The photosensitive composition of claim 1, wherein the photo-initiator comprises at least one selected from the group consisting of:
2,4-bistrichloromethyl-6-p-methoxystyryl-s-triazine, 2-p-methoxystyryl-4,6-bistrichloromethyl-s-triazine, 2,4-trichloromethyl-6-triazine, 2,4-trichloromethyl-4-methylnaphthyl-6-triazine, 2-(o-chlorophenyl)-4,5-diphenyl imidazole dimer, 2-(o-chlorophenyl)-4,5-di(m-methoxyphenyl)imidazole dimer, 2-(o-fluorophenyl)-4,5-diphenyl imidazole dimer, 2-(o-methoxyphenyl)-4,5-diphenyl imidazole dimer, 2,4-di(p-methoxyphenyl)-5-phenyl imidazole dimer, 2-(2,4-dimethoxyphenyl)-4,5-diphenyl imidazole dimer, 2-(p-methylmercaptophenyl)-4,5-diphenyl imidazole dimer, [1-[9-ethyl-6-(2-methylbenzoyl)-9H-carbazolyl-3-yl]-1-(o-acetyloxime), benzophenone, p-(diethylamino)benzophenone, 2,2-dichloro-4-phenoxyacetophenone, 2,2-diethoxyacetophenone, 2-dodecylthioxanthone, 2,4-dimethylthioxanthone, 2,4-diethylthioxanthone, 2,2-bis-2-chlorophenyl-4,5,4,5-tetraphenyl-2-1,2-biimidazole, 2-benzyl-2-dimethylamino-1-(4-morpholinophenyl)-butanone-1,2,2-dimethoxy-1,2-diphenylethan-1-one, 2-methyl-1[4-(methylthio)phenyl]-2-morpholinopropan-1-one, 2,4,6-trimethylbenzoyl-diphenyl-phosphineoxide, and bis(2,4,6-trimethylbenzoyl)-phenylphosphineoxide.

6. The photosensitive composition of claim 1, further comprising a polyfunctional monomer having an ethylene unsaturated bond, wherein an amount of the polyfunctional monomer is between about 5 parts by weight and about 50 parts by weight with respect to the acrylic based copolymer of about 100 parts by weight.

7. The photosensitive composition of claim 1, wherein the photosensitive composition has a solid content of between about 10% by weight and about 50% by weight of the photosensitive composition, and an amount of the solvent is between about 50% by weight and about 90% by weight of the photosensitive composition.

8. A method of manufacturing a substrate used for a display device, the method comprising:
forming a photoresist layer on a substrate, the photoresist layer comprising a photosensitive composition comprising an acrylic based copolymer, a photo-initiator, a photo-sensitizer represented by Chemical Formula 1 and a solvent; and
forming an electrode layer on the photoresist layer; 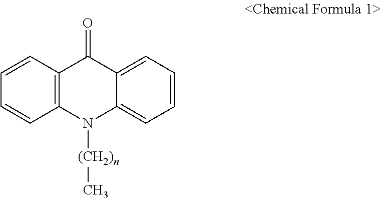
wherein 1≦n≦10.

9. The method of claim 8, wherein an amount of the photo-sensitizer is between about 0.1 parts by weight and about 30 parts by weight with respect to the acrylic based copolymer of about 100 parts by weight.

10. The method of claim 8, wherein the photo-sensitizer absorbs light having a wavelength between about 400 nm and about 410 nm.

11. The method of claim 8, wherein an amount of the photo-initiator is between about 0.1 parts by weight and about 30 parts by weight with respect to the acrylic based copolymer of about 100 parts by weight.

12. The method of claim 8, wherein the photo-initiator comprises at least one selected from the group consisting of:
2,4-bistrichloromethyl-6-p-methoxystyryl-s-triazine, 2-p-methoxystyryl-4,6-bistrichloromethyl-s-triazine, 2,4-trichloromethyl-6-triazine, 2,4-trichloromethyl-4-methylnaphthyl-6-triazine, 2-(o-chlorophenyl)-4,5-diphenyl imidazole dimer, 2-(o-chlorophenyl)-4,5-di(m-methoxyphenyl)imidazole dimer, 2-(o-fluorophenyl)-4,5-diphenyl imidazole dimer, 2-(o-methoxyphenyl)-4,5-diphenyl imidazole dimer, 2,4-di(p-methoxyphenyl)-5-phenyl imidazole dimer, 2-(2,4-dimethoxyphenyl)-4,5-diphenyl imidazole dimer, 2-(p-methylmercaptophenyl)-4,5-diphenyl imidazole dimer, [1-[9-ethyl-6-(2-methylbenzoyl)-9H-carbazolyl-3-yl]-1-(o-acetyloxime), benzophenone, p-(diethylamino)benzophenone, 2,2-dichloro-4-phenoxyacetophenone, 2,2-diethoxyacetophenone, 2-dodecylthioxanthone, 2,4-dimethylthioxanthone, 2,4-diethylthioxanthone, 2,2-bis-2-chlorophenyl-4,5,4,5-tetraphenyl-2-1,2-biimidazole, 2-benzyl-2-dimethylamino-1-(4-morpholinophenyl)-butanone-1,2,2-dimethoxy-1,2-diphenylethan-1-one, 2-methyl-1[4-(methylthio)phenyl]-2-morpholinopropan-1-one, 2,4,6-trimethylbenzoyl-diphenyl-phosphineoxide, and bis(2,4,6-trimethylbenzoyl)-phenylphosphineoxide.

13. The method of claim 8, further comprising a polyfunctional monomer having an ethylene unsaturated bond, wherein an amount of the polyfunctional monomer is between about 5 parts by weight and about 50 parts by weight with respect to the acrylic based copolymer of about 100 parts by weight.

14. The method of claim 8, wherein forming the photoresist layer comprises:
coating the photosensitive composition on the substrate to form a coating layer;
irradiating light having a wavelength between about 400 nm and about 410 nm to at least a portion of the coating layer; and
developing the irradiated coating layer.

15. The method of claim 14, wherein the irradiating light comprises
irradiating a plurality of spot beams using a digital exposure device to the coating layer.

16. The method of claim 15, further comprising: forming a thin-film transistor on the substrate before forming the photoresist layer, the thin-film transistor comprising a gate electrode, a source electrode and a drain electrode,
wherein the photoresist layer comprises a contact hole partially exposing the drain electrode, and the electrode layer comprises a pixel electrode connected to the drain electrode through the contact hole.

17. The method of claim 16, wherein the spot beams are irradiated to be overlapped with each other in regions excluding a contact hole-formed region by selectively actuating micro-mirrors of the digital exposure device, and
wherein the coating layer in the contact hole-formed region is removed by a developing solution.

18. The method of claim 16, wherein forming the thin-film transistor comprises:
forming the gate electrode on the substrate;
continuously forming a semiconductor layer and a source metal layer on the substrate on which the gate electrode is formed;
forming a photo pattern on the source metal layer using the photosensitive composition and the digital exposure device, the photo pattern comprising a first thickness portion having a first thickness and a second thickness portion having a second thickness less than the first thickness;
patterning the semiconductor layer and the source metal layer using the photo pattern to form the source electrode, the drain electrode and an active pattern; and
removing the photo pattern.

19. The method of claim 8, wherein the photosensitive composition further comprises a coloring agent and the electrode layer comprises a common electrode.

20. The method of claim 8, further comprising: forming a color filter using a photosensitive composition comprising a coloring agent before forming the photoresist layer.
